(19) United States
(12) Patent Application Publication
(10) Pub. No.: US 2004/0179566 A1
(43) Pub. Date: Sep. 16, 2004

(54) Multi-color stacked semiconductor lasers

(76) Inventor: Aharon El-Bahar, Haifa (IL)

Correspondence Address: WELSH & KATZ, LTD, 120 S RIVERSIDE PLAZA, 22ND FLOOR, CHICAGO, IL, 60606, US

(21) Appl. No.: 10/385,596

(22) Filed: Mar. 11, 2003

(51) Int. Cl. H01S 3/13; H01S 5/00

(52) U.S. Cl. 372/45

(57) ABSTRACT

A laser device includes a substrate and a multi-layer semiconductor structure formed on the substrate. The structure includes one or more active layers, which are adapted to amplify optical radiation at a plurality of different wavelengths, and at least two reflective regions, arranged to define at least one micro-cavity resonator containing the active layers and having an optical axis substantially perpendicular to the substrate. An electrode is coupled to apply an electrical current to the multi-layer semiconductor structure, causing the structure to emit laser radiation along the optical axis at the plurality of different wavelengths.

### FIELD OF THE INVENTION

The present invention relates generally to opto-electronic semiconductor devices, and specifically to vertical-cavity surface-emitting laser (VCSEL) arrays that are capable of operating at multiple wavelengths simultaneously.

### BACKGROUND OF THE INVENTION

Opto-electronic semiconductor devices, such as light-emitting diodes (LEDs) and semiconductor diode lasers, typically emit radiation in a relatively narrow wavelength band. It is known in the art, however, to combine multiple opto-electronic elements, emitting light at different wavelengths, on a single semiconductor chip. For example, U.S. Pat. Nos. 5,386,428, 5,930,278, 5,982,799 and 6,411,642, whose disclosures are incorporated herein by reference, describe semiconductor laser arrays in which multiple lasers, operating at different wavelengths, are arranged side by side on a chip.

Semiconductor LEDs and diode laser devices emit light due to recombination of electron-hole pairs in an active layer of the device. The wavelength of the radiation is determined by the bandgap in the active layer. It is known in the art to stack two or more active layers, one above the other, on a single substrate in order to generate multi-wavelength radiation. For example, U.S. Pat. No. 5,684,309, whose disclosure is incorporated herein by reference, describes LEDs based on stacked quantum wells, which are designed to emit different wavelengths that combine to produce white light. Stacked laser diode structures are described in U.S. Pat. Nos. 5,138,624, 5,708,674, 5,802,088, and 5,920,766, whose disclosures are also incorporated herein by reference. All these patents describe side-emitting structures, i.e., lasers (or LEDs) that emit radiation along an optical axis parallel to the plane of the substrate.

Unlike conventional side-emitting semiconductor lasers, vertical-cavity surface-emitting laser (VCSELs) emit radiation along an optical axis that is generally perpendicular to the substrate. U.S. Pat. No. 6,174,749, whose disclosure is incorporated herein by reference, describes a multiple-wavelength VCSEL array. The described device uses a wavelength-shifting layer of variable thickness overlying the substrate. The thickness variation defines different VCSEL regions, side-by-side on the substrate, that emit radiation at different wavelengths.

### SUMMARY OF THE INVENTION

Embodiments of the present invention provide novel semiconductor laser devices, which emit laser radiation at multiple wavelengths along a common optical axis that is substantially perpendicular to the device substrate. Such devices typically comprise a VCSEL structure having multiple active layers, which amplify optical radiation at different, respective wavelengths. The VCSEL structure comprises at least two reflective regions, typically in the form of distributed Bragg reflectors, which define at least one micro-cavity resonator, oriented along the optical axis and containing the active layers. One or more electrodes are used to apply an electrical current to the VCSEL structure, causing the structure to emit laser radiation at the multiple different wavelengths simultaneously.

The device may be configured to emit the laser radiation either through the substrate or through one of the electrodes (if a suitable transparent electrode structure is used). In either case, the laser radiation at all the different wavelengths is emitted coaxially, along the same optical axis, as defined by the micro-cavity resonator, unlike the side-by-side beams generated by devices known in the art. The wavelengths of the active layers in the VCSEL structure may be selected to give substantially any output light color, including white light. Furthermore, an array of multi-wavelength VCSEL structures of this sort may be formed together on a common substrate in order to create an intense, high-efficiency light source, which may be used in a wide range of applications.

There is therefore provided, in accordance with an embodiment of the present invention, a laser device, including:

a substrate;

a multi-layer semiconductor structure formed on the substrate, the structure including:

one or more active layers, which are adapted to amplify optical radiation at a plurality of different wavelengths; and

at least two reflective regions, arranged to define at least one micro-cavity resonator containing the active layers and having an optical axis substantially perpendicular to the substrate; and

an electrode, which is coupled to apply an electrical current to the multi-layer semiconductor structure, causing the structure to emit laser radiation along the optical axis at the plurality of different wavelengths.

Typically, the one or more active layers include a plurality of active layers, each of which is adapted to amplify the optical radiation at a respective one of the different wavelengths.

In some embodiments, the active layers include quantum wells having recombination energies that correspond to the different wavelengths. The different wavelengths are determined by selecting at least one of a composition of the quantum wells and a thickness of the quantum wells so as to provide electron and hole energy levels having the recombination energies that correspond to the different wavelengths.

In a disclosed embodiment, the plurality of different wavelengths includes at least first and second wavelengths, and the at least one micro-cavity resonator includes a single resonator containing the active layers and having resonances at the first and second wavelengths. The at least two reflective regions may include first and second distributed Bragg reflectors (DBRs) containing the active layers therebetween, and the DBRs are adapted to reflect the radiation at both the first and second wavelengths. Typically, each of the DBRs includes a stack of alternating DBR layers, each having a respective dielectric index n and a respective thickness t that is chosen so as to satisfy

$$t = \frac{( 4 \times m + 1 ) \times λ}{4 \times n}$$

for λ equal to both of the first and second wavelengths, wherein m is an integer.

In another embodiment, the one or more active layers include first and second active layers, which are adapted to amplify the optical radiation at respective first and second wavelengths, and the at least one micro-cavity resonator includes first and second resonators, coaxially aligned along the optical axis and containing the first and second active layers, respectively. Typically, the device has first and second sides and is arranged so that the laser radiation is emitted through the first side of the device, and the first resonator is located between the second resonator and the first side of the device, and the at least two reflective regions include first and second reflectors, containing the first active layer therebetween, wherein the first and second reflectors are substantially reflective at the first wavelength and substantially transparent at the second wavelength, and third and fourth reflectors, containing the second active layer therebetween, wherein the third and fourth reflectors are substantially reflective at the second wavelength. Alternatively, the at least two reflective regions include first, second and third reflective regions, such that the first and second reflective regions contain the first active layer therebetween and define the first resonator, while the second and third reflective regions contain the second active layer therebetween and define the second resonator.

In an aspect of the invention, the different wavelengths are selected and an intensity of the radiation emitted at each of the different wavelengths is controlled so that the laser radiation is perceived as white light.

There is also provided, in accordance with an embodiment of the present invention, a light source, including:

a substrate;

an array of vertical-cavity surface-emitting laser (VCSEL) structures formed on the substrate, each such VCSEL structure including one or more active layers, which are adapted to amplify optical radiation at a plurality of different wavelengths, the array further including at least two reflective regions, which are arranged to define, in each of the VCSEL structures, at least one micro-cavity resonator containing the active layer and having a respective optical axis passing through the VCSEL structure in a direction substantially perpendicular to the substrate; and

electrodes, which are coupled to apply an electrical current to the VCSEL structures, causing each of the VCSEL structures to emit laser radiation along the respective optical axis at the plurality of different wavelengths.

Typically, the light source includes an integrated circuit chip having pads, to which the electrodes are fixed so as to mount the array of VCSEL structures on the chip and to supply the electrical current through the pads to the electrodes.

There is additionally provided, in accordance with an embodiment of the present invention, a method for producing a light source, including:

forming a multi-layer semiconductor structure on a substrate, the structure including one or more active layers for amplifying optical radiation at a plurality of different wavelengths, and at least two reflective regions, arranged to define at least one micro-cavity resonator containing the active layers and having an optical axis substantially perpendicular to the substrate; and

coupling an electrode to apply an electrical current to the multi-layer semiconductor structure, so as to cause the structure to emit laser radiation along the optical axis at the plurality of different wavelengths.

The present invention will be more fully understood from the following detailed description of the embodiments thereof, taken together with the drawings in which:

### BRIEF DESCRIPTION OF THE DRAWINGS

FIG. 1 is a schematic, pictorial illustration of a multi-wavelength VCSEL structure, in accordance with an embodiment of the present invention;

FIG. 2 is a schematic, sectional illustration showing details of a layer structure in a multi-wavelength VCSEL, in accordance with an embodiment of the present invention;

FIG. 3 is a schematic, sectional illustration showing details of a distributed Bragg reflector (DBR), in accordance with an embodiment of the present invention;

FIGS. 4A and 4B are schematic plots of reflectivity as a function of wavelength for a micro-cavity used in a multi-wavelength VCSEL, in accordance with an embodiment of the present invention;

FIGS. 5-7 are schematic energy level diagrams of quantum well structures in a multi-wavelength VCSEL, in accordance with embodiments of the present invention;

FIGS. 8 and 9 are chromaticity diagrams that schematically illustrate the use of two or three laser wavelengths to create white light;

FIGS. 10 and 11 are schematic, sectional illustrations of multi-wavelength VCSEL structures, in accordance with alternative embodiments of the present invention; and

FIG. 12 is a schematic, sectional illustration of a multi-wavelength VCSEL array, in accordance with an embodiment of the present invention.

### DETAILED DESCRIPTION OF EMBODIMENTS

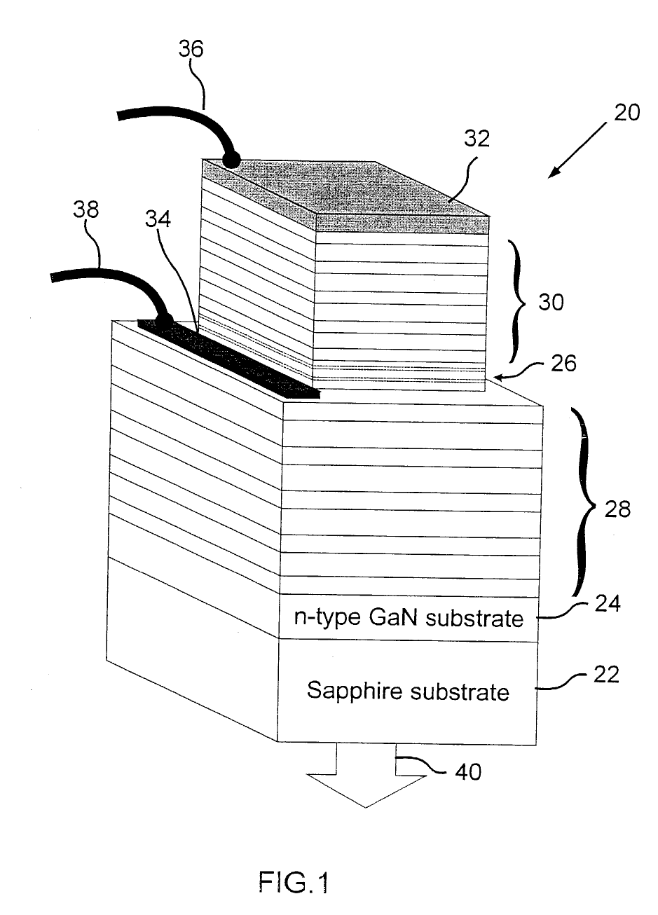

FIG. 1 is a schematic, pictorial illustration of a multi-wavelength VCSEL structure 20, in accordance with an embodiment of the present invention. Structure 20 is typically fabricated on a transparent sapphire substrate 22, using methods of thin film deposition known in the art. The sapphire substrate provides structure 20 with the desired crystalline characteristics, mechanical structure and heat dispersion properties. An n-type GaN substrate layer 24 is deposited on the sapphire substrate. A gain region 26 is contained between a lower distributed Bragg reflector (DBR) 28 and an upper DBR 30, which are formed over the substrate layers. Gain region 26 comprises multiple active layers, each designed to amplify optical radiation at a different, respective wavelength, as described in further detail hereinbelow. Typically, the active layers comprise intrinsic material with multiple quantum wells. Alternatively, gain region 26 may contain a junction between n- and p-type materials.

Lower DBR 28, upper DBR 30 and active layer 26 define an optical microcavity, having resonances at the gain wavelengths of region 26. Lower DBR 28 typically comprises alternating layers of n-type materials, and thus serves both as the lower cavity reflector and as the n-type side of the semiconductor laser junction. In similar fashion, upper DBR 30 comprises alternating layers of p-type materials. The DBRs may comprise compliance layers, as are known in the art, in order to reduce the density of defects therein. Further details of the DBRs are also described below.

Electrodes 32 and 34 contact the p-type upper DER 30 and n-type lower DER 28, respectively. Electrodes 32 and 34 are positively and negatively biased, respectively, via conductors 36 and 38, causing a current to flow through gain region 26. As a result, the VCSEL structure emits a beam of multi-wavelength coherent radiation, represented by an arrow 40, through substrate 22. Alternatively, if electrode 32 is made of a transparent material, the beam may be emitted through the electrode.

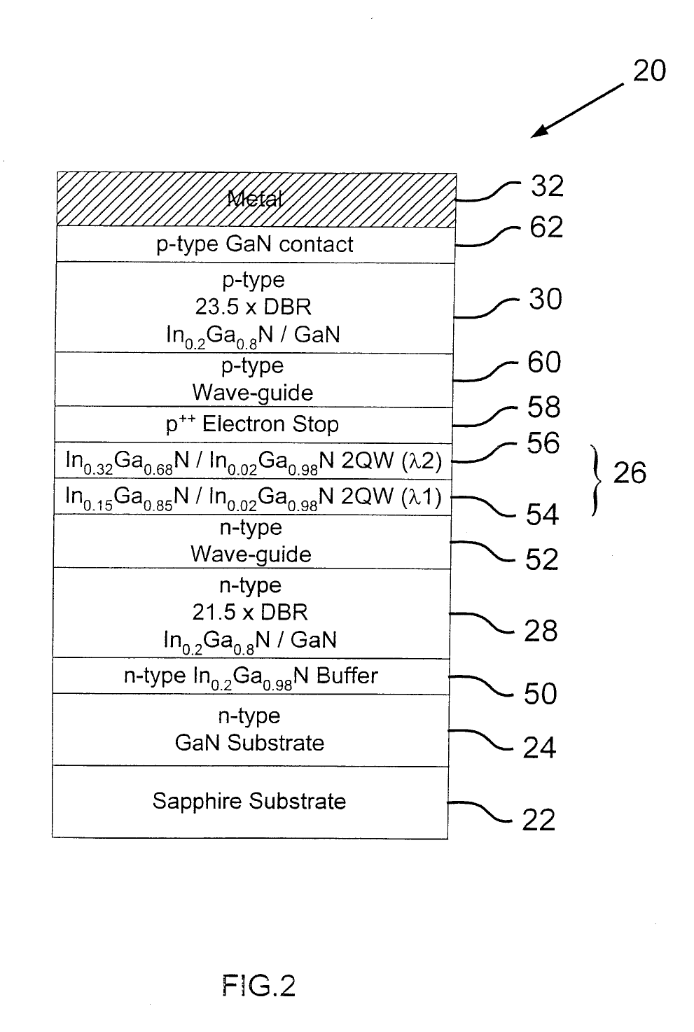

FIG. 2 is a schematic, sectional illustration of structure 20, showing additional details of the layers making up the structure. Reference is also made to Table I, below, which describes quantitatively the composition and thickness of the layers, listed in order from the bottom up (in the frame of reference of FIG. 2).

TABLE I
LAYER COMPOSITION

| | | | Thickness | Doping |
|---|---|---|---|---|
| Layer | | Material | [nm] | [cm⁻³] |
| Sapphire | | Sapphire | 500,000 | — |
| substrate | | (1000) | | |
| GaN substrate | | GaN | 738 | 5 * 10¹⁸ (Si) |
| Buffer | | In_{0.02}Ga_{0.98}N | 183 | 5 * 10¹⁸ (Si) |
| DBR | | GaN | 970 | 5 * 10¹⁸ (Si) |
| 21 | DBR | In_{0.2}Ga_{0.8}N | 907 | 5 * 10¹⁸ (Si) |
| times | DBR | GaN | 970 | 5 * 10¹⁸ (Si) |
| Waveguide | | Al_{0.2}Ga_{0.8}N | 765 | 5 * 10¹⁸ (Si) |
| Barrier | | In_{0.02}Ga_{0.98}N | 321 | 3 * 10¹⁶ (Si) |
| Quantum well | | In_{0.15}Ga_{0.85}N | 5 | 5 * 10¹⁸ (Si) |
| Barrier | | In_{0.02}Ga_{0.98}N | 10 | 3 * 10¹⁶ (Si) |
| Quantum well | | In_{0.15}Ga_{0.85}N | 5 | 5 * 10¹⁸ (Si) |
| Barrier | | In_{0.02}Ga_{0.98}N | 5 | 3 * 10¹⁶ (Si) |
| Barrier | | In_{0.02}Ga_{0.98}N | 5 | 3 * 10¹⁶ (Si) |
| Quantum well | | In_{0.32}Ga_{0.68}N | 4 | 5 * 10¹⁸ (Si) |
| Barrier | | In_{0.02}Ga_{0.98}N | 10 | 3 * 10¹⁶ (Si) |
| Quantum well | | In_{0.32}Ga_{0.68}N | 4 | 5 * 10¹⁸ (Si) |
| Barrier | | In_{0.02}Ga_{0.98}N | 69 | 3 * 10¹⁶ (Si) |
| Electron | | Al_{0.2}Ga_{0.8}N | 20 | 10²⁰ (Mg) |
| stopper | | | | |
| Waveguide | | Al_{0.2}Ga_{0.8}N | 765 | 5 * 10¹⁹ (Mg) |
| DBR | | GaN | 970 | 5 * 10¹⁹ (Mg) |
| 22 | DBR | In_{0.2}Ga_{0.8}N | 907 | 5 * 10¹⁹ (Mg) |
| times | DBR | GaN | 970 | 5 * 10¹⁹ (Mg) |

| | | | |
|---|---|---|---|
| DBR | In_{0.2}Ga_{0.8}N | 907 | 5 * 10¹⁹ (Mg) |
| DBR | GaN | 970 | 5 * 10¹⁹ (Mg) |
| Contact | GaN | 907 | 10²⁰ (Mg) |
| Metal | Ni/Au | 3/10 | — |

GaN substrate 24 is grown on sapphire substrate 22 in order to serve as the base for the structure above it. A compliance layer 50, comprising In_{0.02}Ga_{0.98}N, is used to reduce the stresses caused by the lattice constant mismatch between the sapphire and GaN substrates. Layers 24 and 50 may also referred to as buffer layers.

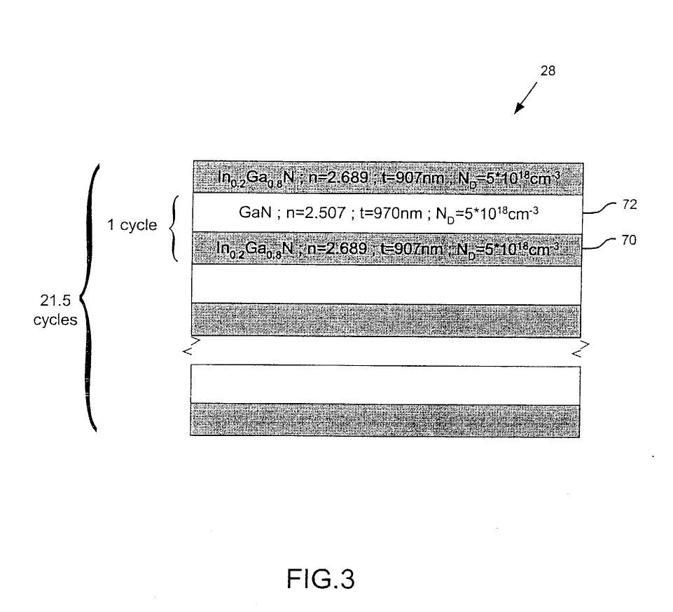

Reference is now made to FIG. 3, which shows details of lower DBR 28, in accordance with an embodiment of the present invention. In the present example, DBR 28 comprises 21.5 cycles of alternating high-index layers 70 and low-index layers 72. The high-index layers comprise In_{0.2}Ga_{0.8}N, while the low-index layers comprise GaN. For both of the laser emission wavelengths, λ₁ and λ₂, Of structure 20, each layer in DBR 28 satisfies the equation:

$$t = \frac{( 4 \times m + 1 ) \times λ}{4 \times n} \qquad ( 1 )$$

Here t is the thickness of the layer, n is the refractive index of the layer, λ is the wavelength and m is an integer. The characteristics of layers 70 and 72 in the present case are chosen for λ₁=463 nm and λ₂=572 nm.

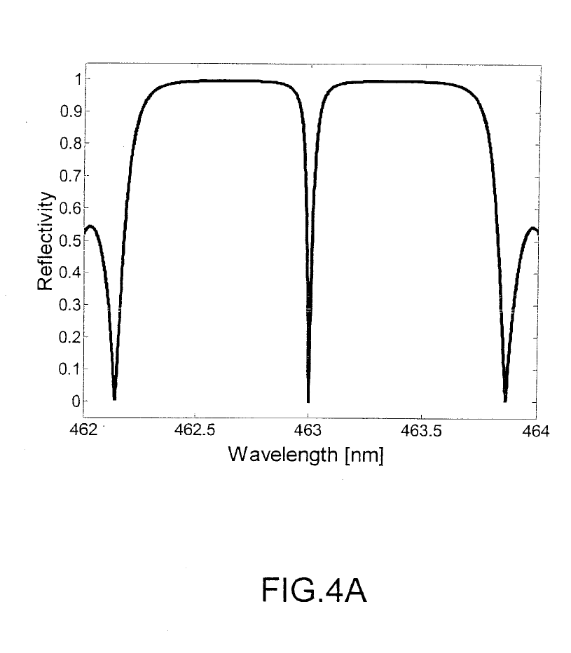

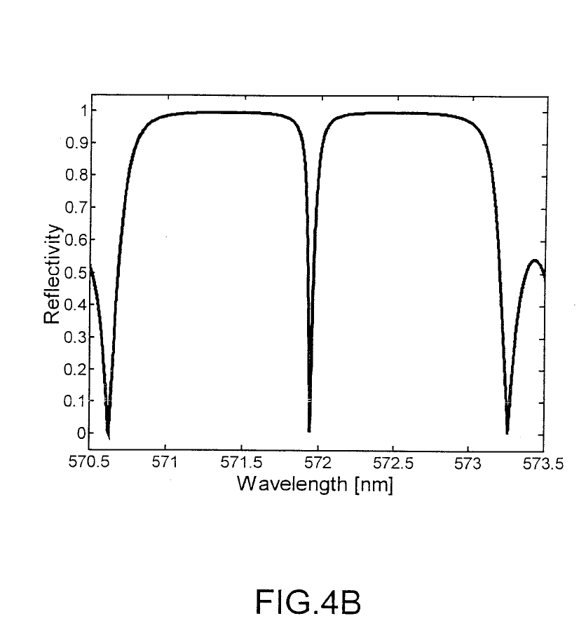

FIGS. 4A and 4B are schematic plots of the reflectivity of the microcavity structure in VCSEL structure 20, as a function of wavelength in the vicinity of the two laser emission wavelengths of structure 20. (The microcavity structure comprises DBR 28, DBR 30, and layers 52-60 shown in FIG. 2.) The reflectivity of each of the DBRs near the Bragg wavelength (with air at both sides) is approximately 0.99. The minimal microcavity reflectivity is achieved at the Bragg frequency, at which each DBR has its maximal reflectivity. Although in the present example, DBRs 28 and 30 are designed to operate at two particular wavelengths, the same approach can be used to design DBRs that support three or more laser wavelengths simultaneously (by satisfying equation (1) at all the wavelengths). As the number of wavelengths that must be supported increases, however, the thickness t of the DBR layers tends to increase, as well.

Returning now to FIG. 2 and Table I, an n-type waveguide layer 52, comprising Al_{0.2}Ga_{0.8}N, is formed over DBR 28. Layer 52 serves as the n-side of the PIN junction containing gain region 26. The gain region comprises two active layers 54 and 56, which comprise quantum wells that are tuned to emit at the laser wavelengths λ₁ and λ₂. Active layers 54 and 56 each comprise alternating layers of intrinsic-type (or lightly doped) material. In the present example, layer 54, which emits at 463 nm, comprises quantum well layers of In_{0.15}Ga_{0.85}N alternating with barrier layers of In_{0.02}Ga_{0.98}N. Layer 56, which emits at 572 nm, comprises quantum well layers of In_{0.32}Ga_{0.68}N alternating with barrier layers of In_{0.02}Ga_{0.98}N.

In order to stop electrons at the upper end of the intrinsic (or lightly doped) region, a heavily-doped, p-type electron stop layer 58 is grown over gain region 26. This layer stops electrons, but allows holes to pass through, so that recombination takes place in the gain region. Layer 58 is overlaid by a p-type waveguide layer 60. Layers 58 and 60 typically comprise Al_{0.2}Ga_{0.8}N. Upper DBR 30 then comprises 23.5 cycles of alternating layers of high-index p-type In_{0.2}Ga_{0.8}N and low-index GaN. The alternating layers here are of the same thicknesses as layers 70 and 72 in lower DBR 28. The use of a higher number (23.5) of cycles in upper DBR 30 causes most of the laser radiation from the microcavity to be emitted through lower DBR 28. The last (upper) cycle of DBR 30, comprising p-type GaN, serves as a contact layer 62. This layer may be doped (more heavily than the layers below it) in order to achieve good ohmic contact with electrode 32.

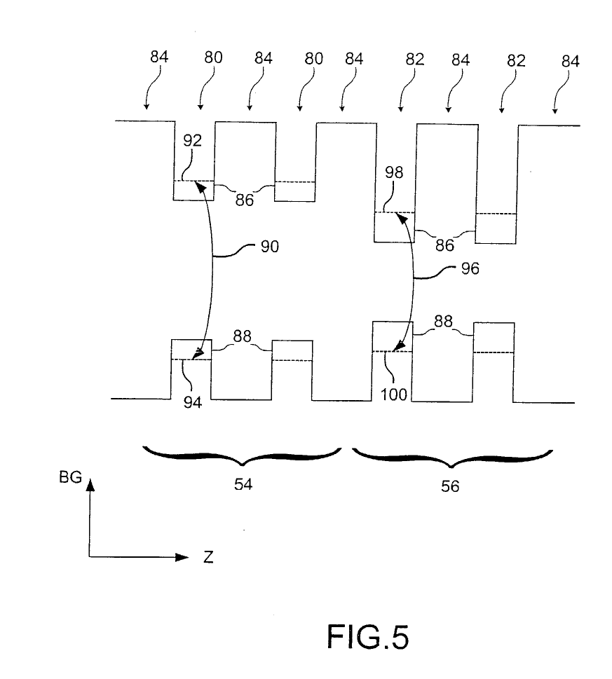

FIG. 5 is a schematic energy level diagram, which shows details of the bandgap structure of active layers 54 and 56, in accordance with an embodiment of the present invention. The horizontal axis in the figure corresponds to the Z-axis (i.e., the vertical axis) in FIG. 2. As noted above, active layers 54 and 56 comprise quantum well layers 80 and 82, respectively, alternating with barrier layers 84. The vertical axis in the figure represents energy levels within the active layers, wherein the upper solid line in the figure represents a conduction band 86, and the lower solid line represents a valence band 88.

Electrons populate energy levels 92 and 98 within conduction band 86 in quantum well layers 80 and 82, while holes populate energy levels 94 and 100 within valence band 88. Recombination of an electron-hole pair in one of the quantum wells causes emission of a photon at a wavelength determined by the difference between the respective electron and hole energy levels, as indicated by arrows 90 and 96 in the figure. In the present example, the energy levels are determined by selecting the appropriate concentrations of In and Ga (or of other suitable quantum well materials) in layers 80 and 82. Thus, the transition indicated by arrow 90 may correspond to emission at 463 nm, while the transition indicated by arrow 96 corresponds to emission at 572 nm. Alternatively, other wavelengths may be generated in like fashion, and further, different quantum well layers may be added so that structure 20 emits laser radiation at three or more wavelengths.

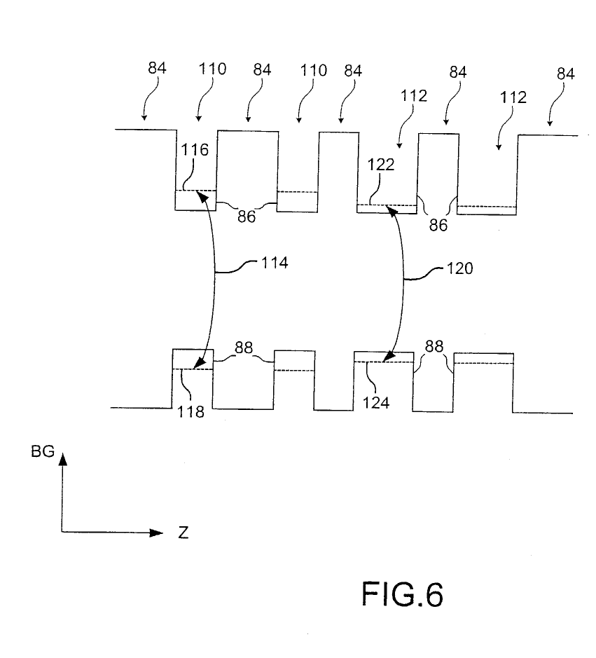

FIG. 6 is a schematic energy level diagram, which shows details of the bandgap structure of two active layers in a multi-wavelength quantum well laser, in accordance with another embodiment of the present invention. This embodiment illustrates an alternative technique for adjusting the wavelength of laser emission, in this case by controlling the thickness of quantum well layers 110 and 112. In thin layer 110, allowed energy levels 116 and 118 are relatively far apart, so that photons emitted due to recombination in this layer have higher energy (shorter wavelength), as indicated by an arrow 114. In thick layer 112, allowed energy levels 122 and 124 are closer together, so that the emitted photons have lower energy (longer wavelength), as indicated by an arrow 120.

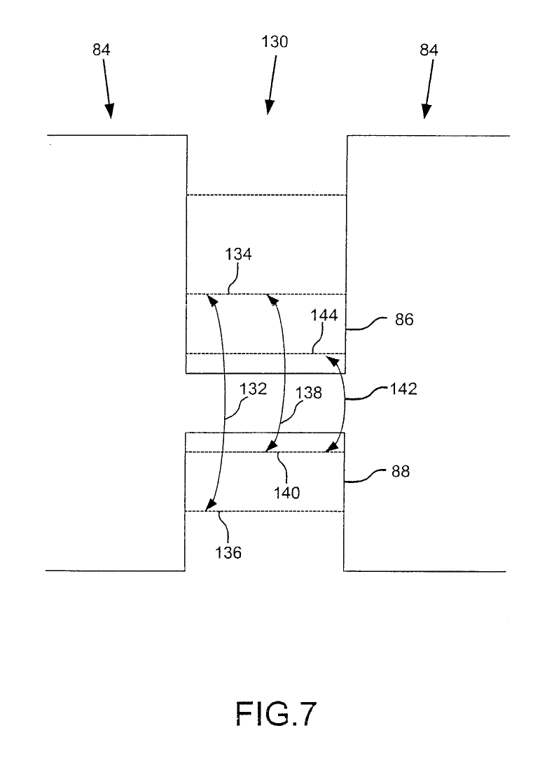

FIG. 7 is a schematic energy level diagram, which shows details of the bandgap structure of an active layer in a multi-wavelength quantum well laser, in accordance with yet another embodiment of the present invention. In this embodiment, a quantum well layer 130 is made sufficiently thick to support multiple electron energy levels 134 and 144 in conduction band 86, and multiple hole energy levels 136 and 140 in valence band 88. Judicious selection of the composition and the thickness of layer 130 allows three specific wavelengths to be generated due to recombination between different pairs of conduction band energy levels 134 and 144 with valence band energy levels 136 and 140, as indicated by arrows 132, 138 and 142.

The methods of wavelength selection exemplified by FIGS. 5, 6 and 7 may be used individually or in combination to generate the desired combination of emission wavelengths. The relative intensities of emission at the different wavelengths may also be controlled. Various methods may be used for this purpose, including varying the distances of the quantum wells from the P- and N-sides of the junction, varying the spacings between the quantum wells, and using different numbers of quantum wells for different wavelengths. Usually, the closer the well is to the P-side the stronger its emission is. By adding more quantum wells to emit light of a certain color, the intensity of that color will be increased, while that of other colors will be reduced. Methods for creating chirped quantum well layers, with different emission frequencies and intensities, are described further, for example, in U.S. Pat. No. 6,504,171, whose disclosure is incorporated herein by reference. The emission wavelengths and intensities may be chosen so that the combined beam is perceived by the human eye as white light, or as substantially any other desired color.

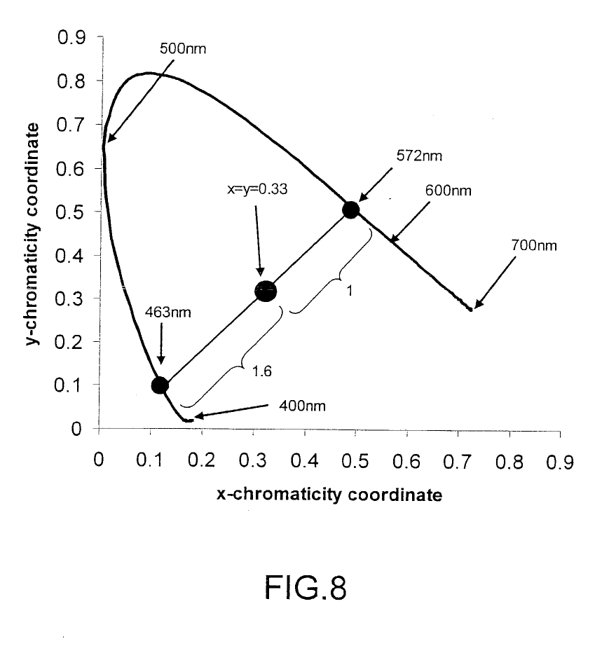

FIG. 8 is a chromaticity diagram, which schematically illustrates the combination of laser radiation from VCSEL structure 20 at two emission wavelengths, λ₁ and λ₂, to generate white light, in accordance with an embodiment of the present invention. Each color in FIG. 8 is represented by corresponding x- and y-chromaticity components, in accordance with the well-known CIE model of human color vision. White light has coordinates x=y=0.33.

As shown in FIG. 8, the CIE diagram can be used to visualize the addition of colors. When multiple wavelengths of light are combined, the resulting color can be found by calculating a weighed average of the original colors using their relative intensities. Thus, two light sources with specific colors can produce a range of colors defined by a line connecting them in the CIE diagram. In the present example, in which active layers 54 and 56 emit light at 463 nm and 572 nm, respectively, it can be seen that an intensity ratio of 1:1.6 between these wavelengths will give a white light output. In other words, driving active layer 54 to emit 1 W of radiation at 463 nm and active layer 56 to emit 1.6 W at 572 will give, in effect, 2.6 W of white light, with an optical efficiency of 412 lumen/W.

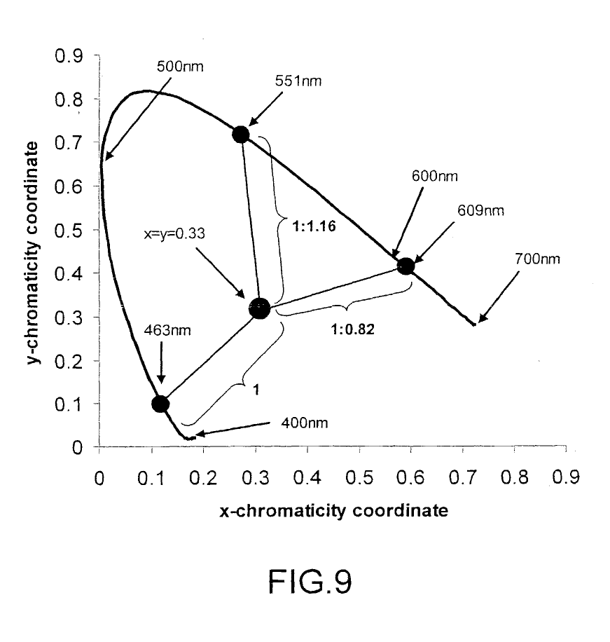

FIG. 9 is a similar chromaticity diagram, which schematically illustrates the combination of laser radiation from a multi-wavelength VCSEL at three simultaneous wavelengths, in accordance with another embodiment of the present invention. Three light sources with specific wavelengths can achieve a range of colors defined by the triangle connecting them in the CIE diagram. In the present example, active layers emitting at 463 nm, 551 nm and 609 nm, respectively, are controlled so as to emit light with an intensity ratio of 1:1.16:0.82, thus generating white light with x=y=0.33. Alternatively, other combinations of two, three or more wavelengths may be used to achieve a similar effect. Using three or more wavelengths simultaneously in this manner allows a large range of colors to be generated by the VCSEL, by varying the relative intensities of emission at the different wavelengths.

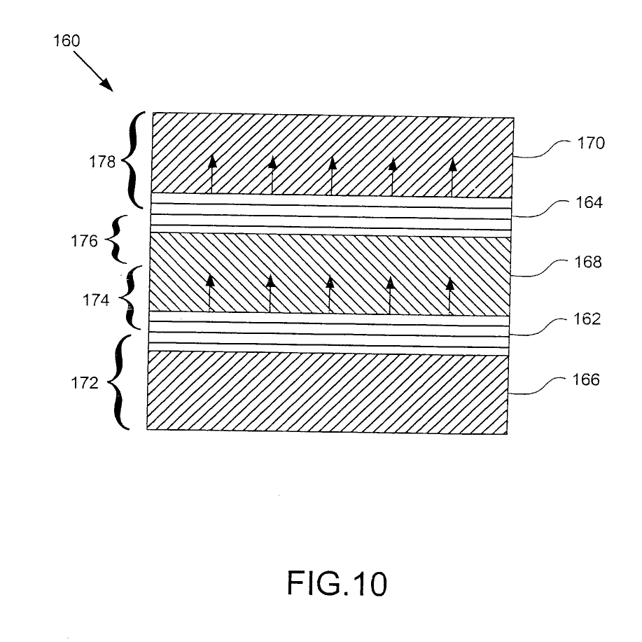

FIG. 10 is a schematic, sectional view of a multi-wavelength VCSEL structure 160, in accordance with another embodiment of the present invention. Details of structure 160 are omitted here for the sake of brevity, but will be apparent to those skilled in the art based on the description of FIGS. 1-7 given above. Structure 160 comprises two separate active regions 162 and 164, each designed to emit radiation at a different, respective wavelength. A lower DBR 166 and a middle DBR 168 (along with active region 162) define the optical microcavity for active region 162, while middle DBR 168 and an upper DBR 170 (along with active region 164) define the optical cavity for active region 164. Typically, active region 162 emits radiation at a longer wavelength than active region 164, and upper DBR 170 is transparent to the longer wavelength. Alternatively, upper DBR 170 may be designed to form a part of the microcavity for the longer-wavelength radiation emitted by active region 162. In either case, the laser radiation from both active regions 162 and 164 is emitted from VCSEL structure 160 in the upward direction (in the frame of reference of the figure) along a common optical axis.

As in the embodiments described above, the emission wavelengths are chosen so as to give output light of a desired color, typically white light. A third active region, with an additional DBR, may similarly be added to generate a third wavelength. Additionally or alternatively, one of the active regions in structure 160, along with its microcavity, may be designed for dual-wavelength operation, as in the embodiment described above.

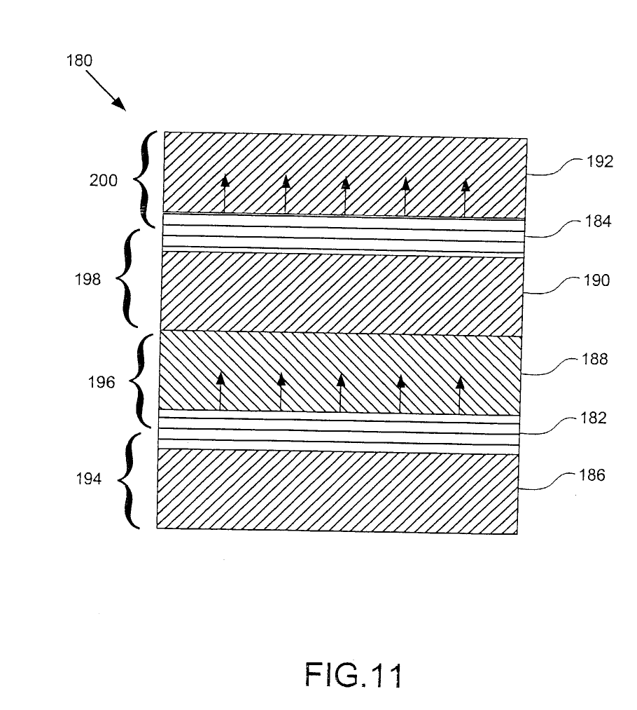

In order to provide carrier injection into both active regions 162 and 164, structure 160 typically has a PNPN arrangement. Thus, regions 172 and 176 may comprise n-type material, while regions 174 and 178 comprise p-type material. Active regions 162 and 164 (and the adjoining waveguide layers) may comprise intrinsic material. Further details of the structure of the layers in FIGS. 10 and 11 may be derived, mutatis mutandis, from the order and composition of the layers listed above in Table I.

FIG. 11 is a schematic, sectional view of a multi-wavelength VCSEL structure 180, in accordance with yet another embodiment of the present invention. In this case, each of active layers 182 and 184 has its own, independent microcavity, wherein the two microcavities are coaxially aligned. The microcavity of active layer 182 comprises DBRs 186 and 188 (together with layer 182), while that of active layer 184 comprises DBRs 190 and 192 (together with layer 184). As in the preceding embodiment, active layer 184 is typically designed to emit radiation at a shorter wavelength than active layer 182, and DBRs 190 and 192 are substantially transparent to the longer-wavelength radiation. Regions 194 and 198 typically comprise n-type material, while regions 196 and 200 comprise p-type material. The multi-wavelength laser beam is emitted from structure 180 in the upward direction.

Although the embodiments described above use certain particular materials and layer structures, and are designed to emit radiation at particular wavelengths, the principles of the present invention may similarly be applied using structures and materials of other types, with different emission wavelengths. For example, the active layers in the laser structures may be based on direct recombination of electrons and holes in a direct band semiconductor, so that the energy bandgap determines the wavelength. As another example, quantum dots, as are known in the art, may be used in the active layer instead of quantum wells. All such alternative implementations are considered to be within the scope of the present invention.

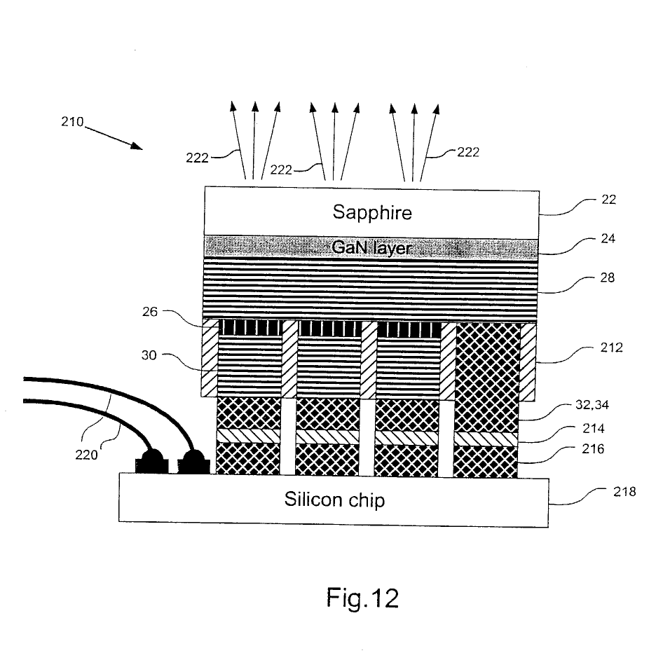

FIG. 12 is a schematic, sectional view of a multi-wavelength VCSEL array 210, in accordance with an embodiment of the present invention. This array comprises a matrix of VCSEL structures, similar to structure 20, shown in FIG. 1, and sharing sapphire substrate 22, GaN substrate 24 and lower DBR 28. To produce active region 26 and upper DBR 30, the required layers are deposited over lower DBR 28, and then these layers are separated, typically using an etching process (or selective growth), to define the individual VCSEL structures in the array. Optionally, lower DBR 28 may be separated among the individual VCSEL structures in this manner, as well, rather than shared among the structures as shown in FIG. 12.

Metal contacts 32 and 34 are formed so as to contact the appropriate points on the VCSEL structure (as illustrated in FIG. 1, for example). An external passivation layer 212 protects the optical and electrical elements of the individual VCSEL structures. Metal contacts 32 are fastened with a conducting glue 214 or a soft metal, such as indium, to thickened pads 216 on a silicon chip 218. External conductors 220 supply electrical current to chip 218 in order to drive the VCSEL structures in array 210. Each of the VCSEL structures emits a multi-wavelength beam through substrate 22, as indicated by arrows 222.

In this manner, array 210 serves as a high-intensity, extended light source, typically a white light source as described above. The light emitted by array 210 is relatively well-collimated, and can be further collimated (or alternatively, diffused) by means of additional, external optics, as are known in the art. Array 210 is capable of running on relatively low DC voltage, which may be supplied by a battery or by an AC/DC or DC/DC converter. The array may be driven by a DC current to emit continuous wave (CW) radiation, or it may alternatively be driven using short, high-current pulses to emit pulsed radiation. The current of the pulses may be chosen so as to optimize the power efficiency of the VCSEL structures, while the duty cycle of the pulses is controlled in order to give the desired output light intensity. If the repetition frequency of the pulses is sufficiently rapid, the pulses will be imperceptible to the human eye. Individual light sources based on a single VCSEL structure, as described above, can also be operated in this manner (i.e., low voltage, CW or pulsed). Another advantage of array 210, however, is that even if certain individual VCSEL structures in the array are inoperative due to defects in the structure, the array as a whole is still capable of generating light of the desired intensity.

Laser light sources produced in accordance with the present invention may be used in a wide range of lighting applications, for example, lighting of homes, industrial spaces, offices, streets and parking lots, as well as automotive headlights and taillights, stage lights, traffic lights, illuminated traffic signs, emergency lights, flashlights and magnifier lights. Such light sources are particularly useful in medical applications, such as overhead lamps and headlamps for surgery and dentistry, as well as miniature light sources for endoscopy and laparoscopy. In these and other applications, the individual multi-wavelength VCSEL structure or array may be combined with beam manipulation optics and other optical elements, as are known in the art, to achieve the desired illumination effects.

It will be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. A laser device, comprising:
a substrate;
a multi-layer semiconductor structure formed on the substrate, the structure comprising:
one or more active layers, which are adapted to amplify optical radiation at a plurality of different wavelengths; and
at least two reflective regions, arranged to define at least one micro-cavity resonator containing the active layers and having an optical axis substantially perpendicular to the substrate; and
an electrode, which is coupled to apply an electrical current to the multi-layer semiconductor structure, causing the structure to emit laser radiation along the optical axis at the plurality of different wavelengths.

2. The device according to claim 1, wherein the one or more active layers comprise a plurality of active layers, each of which is adapted to amplify the optical radiation at a respective one of the different wavelengths.

3. The device according to claim 1, wherein the active layers comprise quantum wells having recombination energies that correspond to the different wavelengths.

4. The device according to claim 3, wherein the different wavelengths are determined by selecting at least one of a composition of the quantum wells and a thickness of the quantum wells so as to provide electron and hole energy levels having the recombination energies that correspond to the different wavelengths.

5. The device according to claim 1, wherein the plurality of different wavelengths comprises at least first and second wavelengths, and wherein the at least one micro-cavity resonator comprises a single resonator containing the active layers and having resonances at the first and second wavelengths.

6. The device according to claim 5, wherein the at least two reflective regions comprise first and second distributed Bragg reflectors (DBRs) containing the active layers therebetween, and wherein the DBRs are adapted to reflect the radiation at both the first and second wavelengths.

7. The device according to claim 6, wherein each of the DBRs comprises a stack of alternating DBR layers, each having a respective dielectric index n and a respective thickness t that is chosen so as to satisfy
$$t = \frac{( 4 \times m + 1 ) \times λ}{4 \times n}$$
for λ equal to both of the first and second wavelengths, wherein m is an integer.

8. The device according to claim 1, wherein the one or more active layers comprise first and second active layers, which are adapted to amplify the optical radiation at respective first and second wavelengths, and
wherein the at least one micro-cavity resonator comprises first and second resonators, coaxially aligned along the optical axis and containing the first and second active layers, respectively.

9. The device according to claim 8, wherein the device has first and second sides and is arranged so that the laser radiation is emitted through the first side of the device, and wherein the first resonator is located between the second resonator and the first side of the device, and
wherein the at least two reflective regions comprise:
first and second reflectors, containing the first active layer therebetween, wherein the first and second reflectors are substantially reflective at the first wavelength and substantially transparent at the second wavelength; and
third and fourth reflectors, containing the second active layer therebetween, wherein the third and fourth reflectors are substantially reflective at the second wavelength.

10. The device according to claim 8, wherein the at least two reflective regions comprise first, second and third reflective regions, such that the first and second reflective regions contain the first active layer therebetween and define the first resonator, while the second and third reflective regions contain the second active layer therebetween and define the second resonator.

11. The device according to claim 1, wherein the different wavelengths are selected and an intensity of the radiation emitted at each of the different wavelengths is controlled so that the laser radiation is perceived as white light.

12. A light source, comprising:
a substrate;
an array of vertical-cavity surface-emitting laser (VCSEL) structures formed on the substrate, each such VCSEL structure comprising one or more active layers, which are adapted to amplify optical radiation at a plurality of different wavelengths, the array further comprising at least two reflective regions, which are arranged to define, in each of the VCSEL structures, at least one micro-cavity resonator containing the active layer and having a respective optical axis passing through the VCSEL structure in a direction substantially perpendicular to the substrate; and
electrodes, which are coupled to apply an electrical current to the VCSEL structures, causing each of the VCSEL structures to emit laser radiation along the respective optical axis at the plurality of different wavelengths.

13. The light source according to claim 12, and comprising an integrated circuit chip having pads, to which the electrodes are fixed so as to mount the array of VCSEL structures on the chip and to supply the electrical current through the pads to the electrodes.

14. The light source according to claim 12, wherein the different wavelengths are selected and an intensity of the radiation emitted at each of the different wavelengths is controlled so that the laser radiation is perceived as white light.

15. A method for producing a light source, comprising:
forming a multi-layer semiconductor structure on a substrate, the structure comprising one or more active layers for amplifying optical radiation at a plurality of different wavelengths, and at least two reflective regions, arranged to define at least one micro-cavity resonator containing the active layers and having an optical axis substantially perpendicular to the substrate; and
coupling an electrode to apply an electrical current to the multi-layer semiconductor structure, so as to cause the structure to emit laser radiation along the optical axis at the plurality of different wavelengths.

16. The method according to claim 15, wherein forming the multi-layer semiconductor structure comprises forming a plurality of active layers, each of which is adapted to amplify the optical radiation at a respective one of the different wavelengths.

17. The method according to claim 15, wherein forming the multi-layer semiconductor structure comprises forming quantum wells in the active layers having recombination energies that correspond to the different wavelengths.

18. The method according to claim 15, wherein the plurality of different wavelengths comprises at least first and second wavelengths, and wherein forming the multi-layer semiconductor structure comprises forming a single resonator containing the active layers and having resonances at the first and second wavelengths.

19. The method according to claim 15, wherein forming the multi-layer semiconductor structure comprises forming first and second active layers, which are adapted to amplify the optical radiation at respective first and second wavelengths, and forming first and second resonators, coaxially aligned along the optical axis and containing the first and second active layers, respectively.

20. The method according to claim 15, wherein forming the multi-layer semiconductor structure comprises selecting the different wavelengths and determining an intensity of the radiation to be emitted at each of the different wavelengths so that the laser radiation is perceived as white light.

21. The method according to claim 15, wherein forming the multi-layer semiconductor structure comprises forming an array of vertical-cavity surface-emitting laser (VCSEL) structures.
